(19) United States
(12) Patent Application Publication
(10) Pub. No.: US 2010/0226170 A1
(43) Pub. Date: Sep. 9, 2010

(54) Non-volatile Memory Array Having Circuitry To Complete Programming Operation In The Event Of Power Interrupt

(75) Inventors: Fong-Long Lin, Fremont, CA (US); Tingniu Deng, San Jose, CA (US)

Correspondence Address: DLA PIPER LLP (US ), 2000 UNIVERSITY AVENUE, EAST PALO ALTO, CA, 94303-2248, US

(73) Assignee: Silicon Storage Technology, Inc.

(21) Appl. No.: 12/398,913

(22) Filed: Mar. 5, 2009

(51) Int. Cl. G11C 16/02; G11C 16/06; G11C 5/14

(52) U.S. Cl. 365/185.03; 365/185.18; 365/226

(57) ABSTRACT

An electrically programmable non-volatile memory device comprises a memory circuit which includes an array of non-volatile memory cells. Each memory cell is capable of being programmed. A programming circuit can generate a programming signal to program one or more of the memory cells. A voltage detector circuit is connected to a voltage source which outputs a certain voltage. The voltage detector circuit detects when the certain voltage has decreased to a certain level, and in response thereto, the voltage detector provides an output signal to the memory controller to complete the on-going programming command sequence and to power down itself. An auxiliary voltage source maintains voltage to the memory circuit for a period of time sufficient for the programming circuit to complete the programming of the one or more of the memory cells, when the certain voltage is at or below the certain level.

### TECHNICAL HELD

The present invention relates to a circuit that addresses the problem of completion of programming operation in a non-volatile memory array in the event of a power interrupt, and more particularly, addresses the problem of a MLC NAND Flash array with paired bits in each cell associated with different pages.

### BACKGROUND OF THE INVENTION

Non-volatile memories and memory devices are well known in the art. Further, non-volatile memory cells of floating gate type wherein charges are stored on a floating gate, which controls the conduction of current in a channel region is also well known. Specifically, referring to FIG. 1 there is shown a schematic block level diagram of a memory device 10 of the prior art. The device 10 comprises well known components such as an address controller 12 for receiving address signals from an address bus 14. The address signals are supplied to an X decoder 16, also commonly known as a row or word line decoder 16. The X decoder 16 receives the address signals and decodes them to produce decoded row signals which are supplied onto row lines, which are connected to the memory array 20. The memory array 20 comprises an array of non-volatile memory cells arranged in a plurality of rows and columns. Each of the memory cells in the array 20 can be of NOR or NAND type. Further, each of the NOR or NAND type memory cell can be SLC (Single Level Cell) or MLC (Multi-Level Cell). In the preferred embodiment each of the memory cell is a MLC Nand memory cell. A reference control circuit 18 is connected to an array of reference non-volatile memory cells 21 and also controls the access of the array 21. The array of reference non-volatile memory cells 21 also comprise an array of reference memory cells arranged in a plurality of rows and columns. In the preferred embodiment, the reference memory cells in the array 21 of reference cells are the same type of non-volatile memory cells as those in the array 20 of memory cells. The array 21 is typically is outside of the main array 20 and is isolated from it physically. In addition, as is well known, a Y decoder 30, also for decoding an address signal is positioned in the column direction and is used to control both the memory array 20 and the reference array 21 (i.e. the Y decoder 30 includes a Y decoder for the main array 20 and a reference Y decoder for the reference array 21). From the output of the Y decoder 30, the column signals or sensed bit signals are supplied to a sense amplifier 32. As is well known, the sense amplifier 32 receives a signal from a selected memory cell from the memory array 20 and a signal from a selected reference cell from the reference array 21, and compares the two to determine the state of storage of the selected memory cell. Other well known components of the memory device 10 include an I/O buffer and controller 34 to receive the output signal from the sense amplifier 32. The memory device 10 further includes a logic controller 40, which controls the operation of the memory device 10, including operations such as programming, erase and reading. Thus, the controller controls the memory array 20 as well as other components. In addition, the memory device 10 comprises other circuits necessary for the operation of the memory device 10, such as high voltage generation circuit 42 and a testing circuit 44. The memory device 10 is typically controlled by a memory controller 60. The memory controller 60 may be electronic circuits that are integrated with the memory device 10 on the same integrated circuit die or it may be a separate integrated circuit die. The memory controller 60 controls the operation of the memory device 10, and thus includes circuitry that performs functions such as: error correction circuitry (ECC), to check for errors stored in the memory array 20; logic circuitry to control the command data sequence for operations of programming, read, and erase; as well as circuitry to power down the memory controller 60. In addition, the memory controller 60 may have storage to store a sequence of operations to be made on the memory device 10.

There are a number of drawbacks of the memory device 10 shown in FIG. 1. In particular, in the event each of the memory cells in the array 20 is a MLC type, each memory cell can store a plurality of bits. Because each cell is a MLC type, during programming of a memory cell, if the programming of that memory cell is interrupted, then incomplete programming of two or more bits results. Further, in the prior art it was common to use ECC (error correction circuitry) to correct errors in either a MLC cell or a NAND memory cell. Since ECC corrects all the errors in a certain size of the array, such as a page, the more errors that occur in the same page, the greater the risk that the ECC cannot correct all the errors. Therefore, in an effort to reduce the number of potential errors in the same page, the plurality of bits that are stored in the same memory cell are associated with a plurality of different pages. Thus, for example, in the event a MLC memory cell stores two or more bits, each of the two or more bits is associated with a different page. In that event, if there is an error in a single memory cell affecting two bits, the result is only one error bit in two or more different pages. This increases the likelihood that ECC can correct the errors in both pages.

However, there is still the need for a memory device in which programming errors are further reduced.

### SUMMARY OF THE INVENTION

An electrically programmable non-volatile memory device comprises a memory circuit which includes an array of non-volatile memory cells. Each memory cell is capable of being programmed. The memory circuit also comprises a programming circuit to generate a programming signal to program one or more of the memory cells. A voltage detector circuit is connected to a voltage source which outputs a certain voltage. The voltage detector circuit detects when the certain voltage has decreased to a certain level, and in response thereto, the voltage detector provides an output signal to the memory circuit to power down the memory circuit. An auxiliary voltage source maintains voltage to the memory circuit for a period of time sufficient for the programming circuit to complete the programming of the one or more of the memory cells, when the certain voltage is at or below the certain level.

### BRIEF DESCRIPTION OF THE DRAWINGS

FIG. 1 is a schematic block diagram of a memory device of the prior art.

FIG. 2 is a first embodiment of a circuit diagram of a portion of the circuit of the present invention to be used with the memory device shown in FIG. 1.

FIG. 3 is a second embodiment of a circuit diagram of a portion of the circuit of the present invention to be used with the memory device shown in FIG. 1.

### DETAILED DESCRIPTION OF THE PREFERRED EMBODIMENT

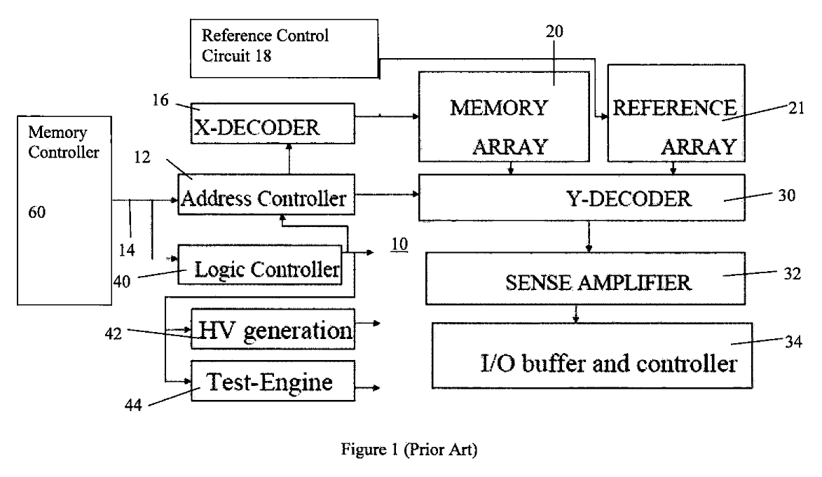

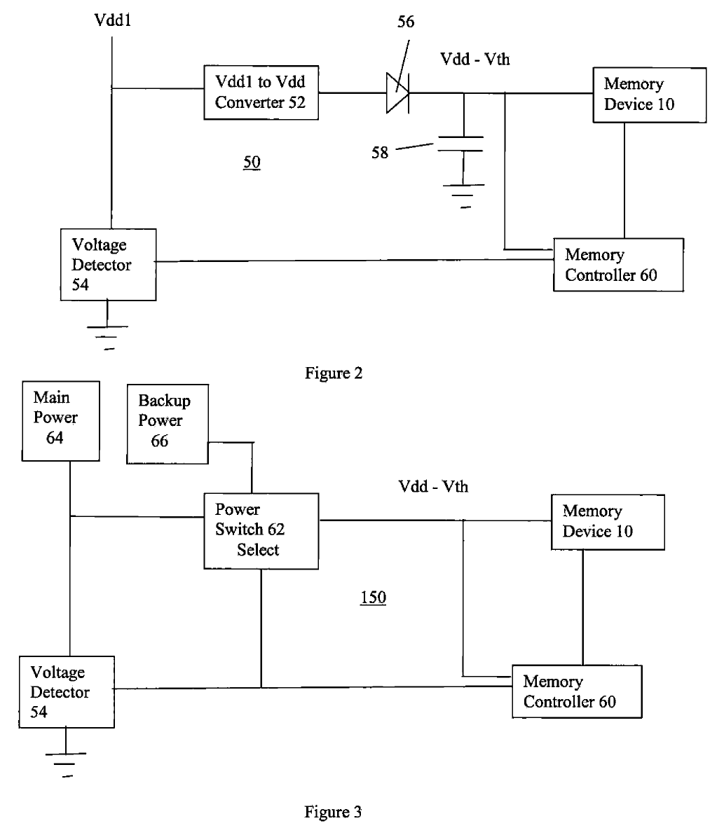

Referring to FIG. 2 there is a shown a circuit diagram of a portion of the circuit 50 of the present invention to be used with the memory device 10 shown in FIG. 1. The circuit 50 receives a voltage Vdd1 from a source. Typically, Vdd1 is a “high” voltage, such as 5.0 volts. It is “high” in the sense that the voltage is higher than what is needed for operation by the memory device 10. Thus, the circuit 50 comprises a Vdd1 to Vdd converter 52. The voltage Vdd is the voltage that is supplied to a forward biased diode 56. In the event Vdd1 is about 5.0 volts, Vdd is on the order of 3.6 volts. The output of the diode 56 is connected to a capacitor 58 and also supplies the voltage Vdd-Vth to the memory device 10, where Vth is the forward bias threshold voltage of the diode 56. In the preferred embodiment, the size of the capacitor is on the order of 300 uf.

The circuit 50 also comprises a voltage detector circuit 54 connected to the voltage Vdd1. The voltage detector circuit 54 detects a drop in voltage in Vdd1. Thus, in the event Vdd1 is on the order of 5.0 volts, the Voltage detector 54 detects when Vdd1 drops to below Vdd or approximately 3.6 volts. In that event, the voltage detector 54 supplies a signal to the power down terminal of the memory controller 60 which causes the memory controller 60 to cease sending any new commands to the memory device 10, except if the memory device 10 is in the programming mode then to complete the programming operation.

In the operation of the circuit 50 with the memory device 10, let's assume that Vdd1 is at 5.0 volts and Vdd for the operation of the memory device is at 3.6 volts. The memory device 10 is capable of operation from 2.7 volts to 3.6 volts, but prefers Vdd-Vth to be at 3.3 volts. When Vdd1 drops below 3.6 volts then the voltage detector 54 generates an interrupt to the memory controller 60, which controls the memory device 10. The memory controller 60 can take two actions: 1) if there isn't any on-going programming operation to the memory device 10, then the memory controller 60 proceeds to step (2). Otherwise, the memory controller 60 will complete the on-going programming operation. Once the programming operation is completed (or if there is no programming operation being executed), then 2) the memory controller 60 will power down itself, and cease executing any other commands or operations that might be stored in the memory controller 60. In addition, it may be necessary for the memory controller 60 to issue a command to the memory device 10 to complete the current operation as soon as possible. Thus, the sequence may be as simple as not issuing any new commands to the memory device 10 or it may be the issuance of a special command to “wrap up” the current operation.

At the same time, when Vdd1 is at or below 3.6 volts, the capacitor 58, which was charged to a level of Vdd-Vth, continues to supply Vdd-Vth voltage to the memory device 10. The capacitor is able to sustain the power to the memory device 10 for the duration of programming (on the order of 3 msec) thereby permitting the memory device 10 complete its programming operation. The diode 56 prevents the voltage at the Vdd-vth terminal from being supplied back from the converter 52 Vdd to Vdd1.

In the preferred embodiment, the circuit 50 is used with a NAND memory device 10 having an array 20 of memory cells which are divided into a plurality of pages, with each memory cell in the array 20 being an MLC cell for storing two or more bits, with each bit associated with a different page. Thus, in the event of programming failure causing both bits in the same cell to be “corrupted” this results in only one bit error in each page. As discussed above, in the event of a decrease in voltage, the memory controller 60, apart from clearing the queue of commands subsequent to the current programming command, it may issue a special wrap up command sequence to make sure that the ongoing programming operation is complete to ensure that the multiple pages data stored in a single cell is programmed correctly and in tact. Of course, the present invention is not limited for use with only NAND MLC cells, but can be used with any non-volatile memory cell in which the programming operation is subject to potential power interrupt thereby causing programming error.

Referring to FIG. 3, there is shown a second embodiment of a portion of the circuit 150 of the present invention to be used with the memory device 10 shown in FIG. 1. The circuit 150 is similar to the circuit 50, and thus like numerals will be used for like parts. The circuit 150 receives a voltage Vdd from a main power source 64. Typically, Vdd is a voltage, such as 3.6 volts which is necessary for the operation of the memory device 10.

The circuit 150 also comprises a voltage detector circuit 54 connected to the main power source 64 and receives the voltage Vdd. The voltage detector circuit 54 detects a drop in voltage in Vdd. Thus, in the event the voltage detector 54 detects when the power from the main power source 64 drops below Vdd, it supplies a signal to the power down terminal of the memory controller 60. The power down terminal causes the memory controller 60 to cease sending any new commands to the memory device 10, except if the memory device 10 is in the programming mode then to complete the programming operation. The signal from the voltage detector 54 is also supplied to w power switch 62. During normal operation, the power switch 62 is in a position to supply the voltage Vdd from the main power source 64 to the memory device 10 and to the memory controller 60. However, when the signal from the voltage detector 54 is received by the power switch 62, it causes the power switch 62 to be set in a position to supply the voltage from a backup power source 64 to the memory controller 60 and to the memory device 10. The voltage and power from the backup power 66 needs to be on only as long as it is necessary for the memory controller 60 to complete the existing programming operation.

As can be seen from the foregoing, the present invention offers the capability of a memory device to complete its programming operation and to shut down itself.

What is claimed is:

1. An electrically programmable non-volatile memory device comprising:
a memory circuit including an array of non-volatile memory cells, each cell capable of being programmed, and a programming circuit for programming one or more of said memory cells;
a voltage detector circuit connected to a voltage source having a certain voltage, said voltage detector circuit for detecting when said certain voltage has decreased to a certain level, and in response thereto, said voltage detector providing an output signal to said memory circuit;
said memory circuit responsive to said output signal to complete any programming operation and to power down said memory circuit thereafter; and
an auxiliary voltage source for maintaining voltage to said memory circuit for a period of time sufficient for said programming circuit to complete the programming of said one or more of said memory cells, when said certain voltage is at or below said certain level.

2. The memory device of claim 1 wherein each of said memory cells is a non-volatile memory transistor having a floating gate for storing charges thereon.

3. The memory device of claim 2 wherein said array of non-volatile memory cells is an array of NAND memory cells.

4. The memory device of claim 2 wherein said array of non-volatile memory cells is an array of NOR memory cells.

5. The memory device of claim 3 wherein each of said memory cells is a MLC memory cell storing a plurality of bits.

6. The memory device of claim 5 wherein said array of NAND memory cells is divided into a plurality of pages.

7. The memory device of claim 6 wherein the plurality of bits in each memory cell are associated with a plurality of different pages.

8. The memory device of claim 7 wherein each MLC memory cell stores two or more bits.

9. The memory device of claim 8 wherein each of the two or more bits in a MLC memory cell is associated with a different page.

10. The memory device of claim 1 wherein memory circuit comprises a memory array and a memory controller.

11. The memory device of claim 10, wherein said memory controller is responsive to said output signal to complete any programming operation of said memory array and to power down said memory array thereafter.

12. The memory device of claim 11 wherein said memory controller is also responsive to said output signal to power down said memory controller after the completion of any programming operation of said memory array.
